(19) United States
(12) Patent Application Publication
(10) Pub. No.: US 2025/0183036 A1
(43) Pub. Date: Jun. 5, 2025

(54) SELECTIVE SILICON NITRIDE WITH TREATMENT FOR CONTACT FORMATION IN LOGIC OR MEMORY DEVICES

(71) Applicant: Applied Materials, Inc., Santa Clara, CA (US)

(72) Inventors: Naomi Yoshida, Sunnyvale, CA (US); Balasubramanian Pranatharthiharan, San Jose, CA (US); Hsueh Chung Chen, Cohoes, NY (US); Joseph Shepard, Saratoga Springs, NY (US); Scott A. DeVries, Albany, NY (US); Theresa K. Guarini, San Jose, CA (US); Wei Liu, San Jose, CA (US)

(73) Assignee: Applied Materials, Inc., Santa Clara, CA (US)

(21) Appl. No.: 18/950,673

(22) Filed: Nov. 18, 2024

Related U.S. Application Data
(60) Provisional application No. 63/605,260, filed on Dec. 1, 2023.

(51) Int. Cl. H01L 21/033; H01L 21/02

(52) U.S. Cl. CPC H01L 21/0337; H01L 21/02642

(57) ABSTRACT

Methods of manufacturing logic or memory devices are provided. The method comprises pre-cleaning a surface of a transistor device, the transistor device comprising a first source/drain material and a second source/drain material; exposing the surface of the transistor device to a growth inhibitor; selectively depositing a silicon-containing mask layer source/drain material; and densifying the silicon-containing mask layer. The processing method is performed in a processing tool without breaking vacuum.

### CROSS REFERENCE TO RELATED APPLICATIONS

This application claims priority to U.S. Provisional Application Ser. No. 63/605,260, filed Dec. 1, 2023, the entire disclosure of which is hereby incorporated by reference herein.

### TECHNICAL FIELD

Embodiments of the present disclosure pertain to the field of electronic devices and methods and apparatus for manufacturing electronic devices. More particularly, embodiments of the disclosure provide methods for forming logic or memory device devices with high quality silicon-containing dielectric layers.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor structures include a planar structure, a fin field effect transistor (FinFET) structure, a complementary field effect transistor (CFET) structure, and a gate all around (GAA) structure. Logic gate performance is related to the characteristics of the materials used as well as the thickness and area of the structural layers. However, as some gate characteristics are adjusted to accommodate device scaling, challenges arise.

Current processes employed in GAA manufacturing use non-selective atomic layer deposition (ALD), plasma enhanced atomic layer deposition (PEALD), or chemical vapor deposition (CVD) of silicon nitride (SiN) with subsequent additional patterning steps. Selective deposition of SiN can reduce the number of patterning steps. Selective deposition, however, requires relatively low deposition temperatures, which yield poor quality films.

Accordingly, there is a need in the art for logic or memory devices having high quality SiN films. Additionally, there is a need in the art for methods and apparatus for forming the logic or memory devices.

### SUMMARY

One or more embodiments of the disclosure are directed to a processing method to form a semiconductor device. In one or more embodiments, the processing method comprises: pre-cleaning one or more a first transistor or a second transistor; selectively depositing a silicon-containing mask layer on one or more of a first region of the first transistor or a second region of the second transistor; and densifying the silicon-containing mask layer to form a densified silicon-containing mask layer having a density gradient.

Further embodiments of the disclosure are directed to processing methods to form a logic or memory device. In one or more embodiments, a processing method to form a logic or memory device comprises: pre-cleaning one or more of a first transistor or a second transistor; exposing one or more of the first transistor or the second transistor to a growth inhibitor; selectively depositing a silicon-containing mask layer on a first region of the first transistor or on a second region of the second transistor; densifying the silicon-containing mask layer to form a densified silicon-containing mask layer having a density gradient; and repeating one or more of: pre-cleaning one or more of the first transistor or the second transistor, exposing one or more of the first transistor or the second transistor to the growth inhibitor, selectively depositing the silicon-containing mask layer, and densifying the silicon-containing mask layer, wherein the processing method is performed in a processing tool without breaking vacuum.

Additional embodiments of the disclosure are directed to processing tools. In one or more embodiments, a processing tool comprises: a central transfer station comprising a robot configured to move a wafer; a plurality of process stations; and a controller configured to activate the robot to move the wafer between the process stations, and to control a process comprising: pre-cleaning one or more of a first transistor or a second transistor; selectively depositing a silicon-containing mask layer on one or more of a first region of the first transistor or a second region of the second transistor; and densifying the silicon-containing mask layer to form a densified silicon-containing mask layer having a density gradient, wherein the operations are performed without breaking vacuum.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments described herein are illustrated by way of example and not limited in the figures of the accompanying drawings in which like references indicate similar elements.

FIG. 1A depicts a process flow diagram of a method according to one or more embodiments described herein;

FIG. 1B depicts a process flow diagram of a method according to one or more embodiments described herein;

FIG. 2 illustrates a cross-sectional view of a device according to one or more embodiments;

FIG. 3 illustrates a cross-sectional view of a device according to one or more embodiments;

FIG. 4 illustrates a cross-sectional view of a device according to one or more embodiments;

FIG. 5 illustrates a cross-sectional view of a device according to one or more embodiments;

FIG. 6 illustrates a cross-sectional view of a device according to one or more embodiments;

FIG. 7 illustrates a cross-sectional view of a device according to one or more embodiments; and

FIG. 8 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas”, and the like are used interchangeably to refer to any gaseous species that can react with the substrate surface.

“Epitaxy” is a process by which a deposited film is forced into a high degree of crystallographic alignment with the substrate. Epitaxial growth is broadly defined as the condensation of gas precursors to form a film on a substrate. Liquid precursors may also be used. Vapor precursors may be obtained by chemical vapor deposition (CVD) and laser ablation. Several epitaxy techniques are now available, such as molecular beam epitaxy (MBE), epitaxial CVD, or atomic layer epitaxy (ALE).

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

One example of gate-all-around (GAA) technology is complementary field effect transistor (CFET). As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors. CFET transistors have increased on-chip device density and reduced area consumption when compared to GAA transistors.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

One or more embodiments provide a processing method in an integrated processing tool to permit selective deposition of silicon-containing mask layers, e.g., silicon nitride, on a sidewall through a high aspect ratio opening in a transistor.

Selective deposition of silicon-containing mask layers, e.g., silicon nitride, is a low temperature process that results in poor quality films. Without intending to be bound by theory, it is thought that if the poor quality selectively deposited silicon-containing mask layers cannot be converted to high quality silicon-containing films, selectively deposited silicon-containing films, particularly silicon nitride, cannot be used to form useful memory and logic structures.

Although the disclosure will routinely identify specific NMOS and PMOS devices, and components thereof, it will be readily understood that the device and methods are equally applicable to other field-effect transistors (e.g., GAA, FinFETs, and CFETs), orientations thereof, as processes for forming such devices. Accordingly, the technology should not be considered to be so limited as for use with these specific devices or methods alone. The disclosure will discuss one possible semiconductor device that may include one or more components, utilizing one or more a bilayer dielectric wall according to embodiments of the present technology before additional variations and adjustments to this apparatus according to embodiments of the present technology are described.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, transistors, and logic or memory devices, e.g., gate all-around transistors, FinFETs, CFETS, NMOS, PMOS, and the like, are fabricated. In specific embodiments, n-channel field-effect transistors and p-channel field-effect transistors such as NMOS and/or PMOS structures are fabricated. Specifically, provided are processes for forming contacts on both n-channel field-effect transistors and p-channel field-effect transistors. In some embodiments, the method comprises pre-cleaning a top surface of n-channel field-effect transistors or p-channel field-effect transistors structure; exposing the top surface of the n-channel field-effect transistors or p-channel field-effect transistors to a growth inhibitor; selectively depositing a silicon-containing dielectric layer in a source/drain region of n-channel field-effect transistors or the p-channel field-effect transistors; and densifying the silicon-containing dielectric layer. In some embodiments, the processing method is performed in a processing tool without breaking vacuum.

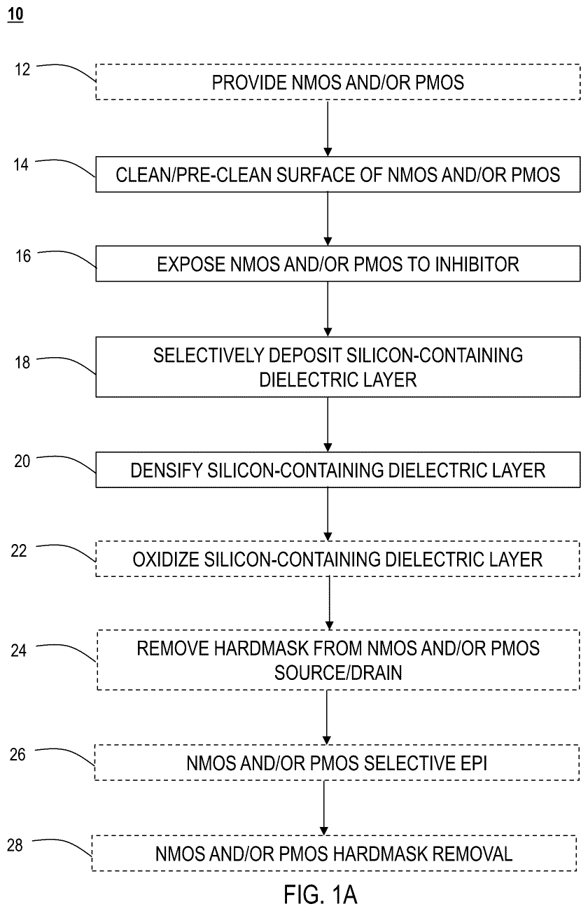

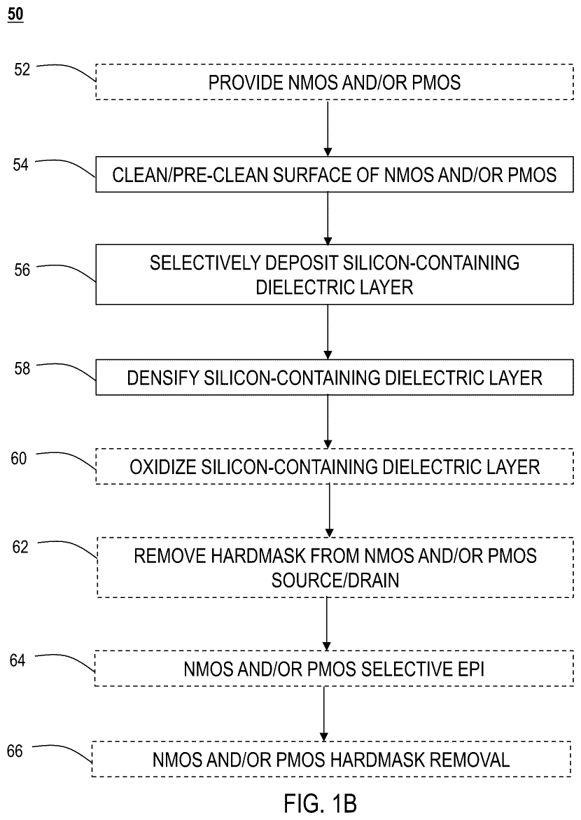

FIG. 1A illustrates a process flow diagram for an exemplary method 10 for forming a logic or memory device. The skilled artisan will recognize that the method 10 can include any or all of the processes illustrated. Additionally, the order of the individual processes can be varied for some portions. The method 10 can start at any of the enumerated processes without deviating from the disclosure. With reference to FIG. 1A, at operation 12, an NMOS and/or a PMOS is provided. As used herein, the term “provided” means that the substrate is made available for processing (e.g., positioned in a processing chamber). At operation 14, the surface of the NMOS and/or PMOS is cleaned of any impurities, e.g., native oxide. At operation 16, the NMOS and/or PMOS is exposed to a growth inhibitor. At operation 18, a silicon-containing dielectric layer is selectively deposited in a region of the NMOS and/or PMOS. At operation 20, the silicon-containing dielectric layer is densified. At operation 22, the silicon-containing dielectric layer may be optionally oxidized. At operation 24, the NMOS and/or PMOS source/drain is etched and cleaned. Specifically, in one or more embodiments, at operation 24, the hardmask is removed from the NMOS source/drain, while keeping the hardmask on the PMOS source/drain. At operation 26, an epitaxial layer is then selectively grown on the source/drain of the NMOS. Alternatively, at operation 24, the hardmask is removed from the PMOS source/drain, while the hardmask remains on the NMOS source/drain, and, at operation 26, an epitaxial layer is then selectively grown on the source/drain of the PMOS. At operation 28, the hardmask is removed from the source/drain of the NMOS or the PMOS.

The method 10 of one or more embodiments is an integrated method. In one or more embodiments, the method 10 may be performed in one or more processing chamber without breaking vacuum between any of the operations 12, 14, 16, 18, 20, and 22. In one or more embodiments, the method 10 may be performed in one or more processing chamber without breaking vacuum between any of the operations 12, 14, 16, 18, 20, 22, 24, 26, and 28.

FIG. 1B illustrates a process flow diagram for an exemplary method 50 for forming a logic or memory device. The skilled artisan will recognize that the method 50 can include any or all of the processes illustrated. Additionally, the order of the individual processes can be varied for some portions. The method 50 can start at any of the enumerated processes without deviating from the disclosure. With reference to FIG. 1B, at operation 52, an NMOS and/or PMOS is provided. At operation 54, the surface of the NMOS and/or PMOS is cleaned of any impurities, e.g., native oxide. At operation 56, a silicon-containing mask layer is selectively deposited in a region of the NMOS and/or PMOS. At operation 58, the silicon-containing mask layer is densified. At operation 60, the silicon-containing dielectric layer may be optionally oxidized. At operation 62, the NMOS and/or PMOS source/drain is etched and cleaned. Specifically, in one or more embodiments, at operation 62, the hardmask is removed from the NMOS source/drain, while keeping the hardmask on the PMOS source/drain. At operation 64, an epitaxial layer is then selectively grown on the source/drain of the NMOS. Alternatively, at operation 62, the hardmask is removed from the PMOS source/drain, while the hardmask remains on the NMOS source/drain, and, at operation 64, an epitaxial layer is then selectively grown on the source/drain of the PMOS. At operation 66, the hardmask is removed from the source/drain of the NMOS or the PMOS.

The method 50 of one or more embodiments is an integrated method. In one or more embodiments, the method 50 may be performed in one or more processing chamber without breaking vacuum between any of the operations 52, 54, 56, 58, and 60. In one or more embodiments, the method 50 may be performed in one or more processing chamber without breaking vacuum between any of the operations 52, 54, 56, 58, 60, 62, 64, and 66.

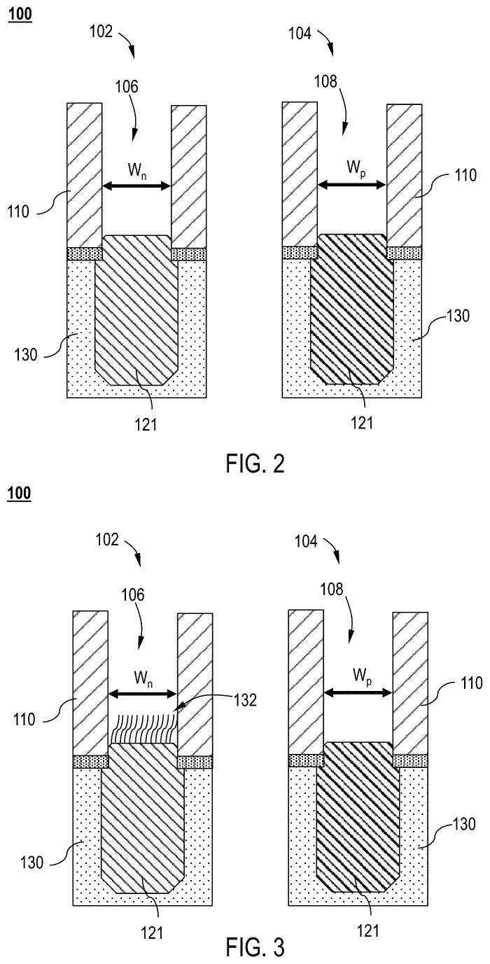

With reference to FIGS. 2-7, a semiconductor structure 100 is shown. The semiconductor structure 100 comprises an n transistor 102 and a p transistor 104. In one or more embodiments, each of the n transistor 102 and the p transistor 104 comprise a spacer 110, a source/drain material 120,121, and a substrate 130.

In one or more embodiments, the spacer 110 may comprise any suitable dielectric material known to the skilled artisan. In some embodiments, the spacer 110 comprises one or more of silicon, silicon oxide (SiOx), silicon nitride (SIN), silicon carbide (SiC), silicon oxycarbide (SiCO), silicon oxycarbonitride (SiOCN), and the like. As used herein, terms such as “silicon oxide” and “silicon nitride” refer to materials comprising silicon and oxygen or silicon and nitrogen. “Silicon oxide” and “silicon nitride” should not be understood to imply any stoichiometric ratio. Stated differently, a dielectric material comprising silicon oxide or silicon nitride may be stoichiometric or non-stoichiometric, silicon-rich, or silicon-poor. In some embodiments, the spacer 110 comprises one or more of silicon oxycarbide (SiCO), silicon boron nitride (SiBN), silicon oxyboronitride (SiBON), and silicon oxycarbonitride (SiOCN).

In some embodiments, the n transistor 102 and the p transistor 104 comprise source and drain contacts. In one or more embodiments, the source/drain material 120,121 may have more than one layer. In some embodiments, the source/drain material 120, 121 comprises a layer of silicon with doped epi (e.g., Si, SiGe, and the like doped with one or more dopant), a second layer of silicide, which may contain nickel (Ni), titanium (Ti), aluminum (Al), and the like, and a third, or top, layer which may be a metal such as, but not limited to, cobalt, tungsten, ruthenium, aluminum, and the like.

In one or more specific embodiments, the source/drain material 120 of the n transistor 102 comprises silicon (Si) doped with phosphorous (P). In one or more embodiments, the source/drain material 120 of the n transistor 102 has a bandgap in a range of about 1.0 eV to about 1.2 eV.

In one or more embodiments, the source/drain material 121 of the p transistor 104 comprises silicon germanium (SiGe) doped with boron (B). In one or more embodiments, the source/drain material 121 of the p transistor 104 has a bandgap in a range of about 0.5 eV to about 1.0 eV.

Referring to FIGS. 2-7, there is a first opening 106 over the n transistor 102, and there is a second opening 108 over the p transistor 104. The first opening 106 and the second opening 108 can have any suitable aspect ratio (ratio of the depth of the opening to the width of the opening). In one or more embodiments, the first opening 106 and the second opening 108 may independently have an aspect ratio in a range of from 3:1 to 15:1, from 6:1 to 15:1, from 9:1 to 15:1, from 12:1 to 15:1, or an aspect ratio greater than 10:1. The first opening 106 over the n transistor 102, and there is a second opening 108 over the p transistor 104 each have sidewalls that extend to the source/drain material 120. In some embodiments, the first opening 106 has a width, Wₙ, and the second opening 108 has a width, Wₚ.

The substrate 130 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

Referring to FIG. 1A and FIG. 2, at operation 14, the exposed surface(s), e.g., sidewall surface of the spacer 110 and the top surface of the source/drain material 120, 121, may be cleaned/pre-cleaned. In some embodiments, the clean/pre-clean process comprises a sublimation etch for native oxide removal. The etch process can be plasma or thermally based. The plasma processes can be any suitable plasma (e.g., conductively coupled plasma, inductively coupled plasma, microwave plasma). In one or more embodiments, the clean process may include a conventional plasma etch, or a remote plasma-assisted dry etch process. In the etch process of one or more embodiments, the device or film stack is exposed to H₂, NF₃, and/or NH₃ plasma species, e.g., plasma-excited hydrogen and fluorine species. For example, in some embodiments, the device or film stack may undergo simultaneous exposure to H₂, HF, NF₃, and NH₃ plasma. The etch process may be performed in a preclean chamber, which may be integrated into one of a variety of multi-processing platforms. The wet etch process may include a hydrofluoric (HF) acid last process, i.e., the so-called “HF last” process, in which HF etching of the surface is performed that leaves the surface hydrogen-terminated. Alternatively, any other liquid-based pre-clean process may be employed. In one or more embodiments, the pre-cleaning of operation 14 is optional. Thus, in one or more embodiments, the pre-clean does not occur.

Referring to FIG. 1A, in one or more embodiments, at operation 16, the electronic device 100 is exposed to a growth inhibitor to avoid or prevent deposition on one or more of the source/drain material 120,121 of the n-transistor 102 or the p-transistor 104. The growth inhibitor may be added on the source/drain material 120, 121 to prevent deposition on the other of the source/drain material 120,121. In some embodiments, operation 16 is optional. Thus, in one or more embodiments, the electronic device is not exposed to a growth inhibitor but instead proceeds directly to operation 18.

In one or more embodiments, with reference to FIG. 1A and FIG. 3, at operation 16, a surface treatment, e.g., exposure to a growth inhibitor, is used to ensure that different terminating groups are present on the source/drain material 120, 121 so that a subsequent ALD of CVD film growth will be differentiated based on the difference surfaces. For example, to prepare a bare Si surface terminated with Si—H groups, dilute HF wet clean, a dry clean, or a plasma-based dry clean can be used to remove native oxide on Si surface and form Si—H bonds. To prepare a passivated surface that can block ALD film growth, a hydrophobic surface monolayer can be formed on silicon oxide surface. For example, alkylamino silane can be adsorbed onto silicon oxide surface to form alkyl silyl groups on SiO surface. The ALD film growth chemistry of some embodiments is based on silicon halide and ammonia reactions which can selectively grow on bare Si surface but not a passivated SiO surface. The maximum thickness achievable by some embodiments is about 100 Å growth on bare Si, with substantially no film growth on the passivated SiO surface. Periodic SiO and/or SiOC surface regeneration and passivation could be used to make thicker growth on bare Si than SiO.

Operation 16, in accordance with one or more embodiments of the disclosure, may involve the formation of a blocking layer 132 having a hydroxyl-terminated surface on the top surface of the source/drain material 120 of the n-transistor 102, while the source/drain material 121 of the p-transistor 104 may have a hydrogen-terminated surface. In other embodiments, a blocking layer 132 having a hydroxyl-terminated surface may be formed on the top surface of the source/drain material 121 of the p-transistor 104, while the source/drain material 120 of the n-transistor 102 may have a hydrogen-terminated surface. In some unillustrated embodiments, the source/drain material 120,121 may also have some native oxide formed thereon. Those skilled in the art will understand that the surface atom bonding is not always simple. For example, an oxide surface can be a bridged oxygen atom bonded to more than one silicon atom and that the stoichiometry of the surface and bulk composition are not necessarily one-to-one.

The source/drain material 120 and the source/drain material 121 can be any suitable surfaces for selective deposition. In some embodiments, the source/drain material 120 is a dielectric surface with-OH ending groups and source/drain material 121 comprises a silicon surface with Si—H groups with or without native oxide. In some embodiments, the source/drain material 121 comprises a dielectric surface with-OH ending groups and the source/drain material 120 comprises a silicon surface with Si—H groups with or without native oxide.

If a native oxide is present on the source/drain material 120,121, removal of the native oxide may allow for a more effective selective deposition process. Exposing the device 100 to an etch process can remove the native oxide from the source/drain material 120,121. The etch process can be a wet etch process (e.g., exposure to dilute HF (1%)) or a dry etch process (e.g., exposure to a plasma). In some embodiments, the etch process is a plasma-based process. In some embodiments, the plasma-based etch process comprises exposing the substrate to a plasma of ammonia and hydrofluoric acid.

In some embodiments, removing the native oxide from the source/drain material 120,121 provides a surface with substantially only hydrogen terminations. As used in this manner, the term “substantially only hydrogen terminations” means that the surface terminations are hydrogen for greater than or equal to about 98% of the surface area. In some embodiments, removing the native oxide from the source/drain material 120,121 provides a surface with substantially no oxygen terminations. As used in this manner, the term “substantially no oxygen terminations” means that the surface terminations comprise less than about 2% of the surface area comprises oxygen atoms.

In one or more embodiments, the process used to remove the native oxides from the source/drain material 120 of the n-transistor 102 also oxidizes the source/drain material 121 of the p-transistor 104 to provide a surface with substantially no hydrogen terminations. As used in this manner, the term “substantially no hydrogen terminations” means that the surface terminations of the stated surface are hydrogen for less than or equal to about 2% of the surface area. In some embodiments, the source/drain material 121 comprises substantially only hydroxyl terminations. As used in this manner, the term “substantially only hydroxyl terminations” means that the surface terminations for the subject surface are hydroxyl groups for greater than or equal to about 98% of the surface area.

The device, including the source/drain material 120, 121, can be exposed to a growth inhibitor to react with the hydroxyl-terminated surface to form a blocking layer 132. The growth inhibitor of some embodiments comprises an alkyl silane. In some embodiments, has a general formula SiR₄, where each R is independently a C₁-C₆ alkyl, a substituted or unsubstituted amine, a substituted or unsubstituted cyclic amine.

In some embodiments, the alkyl silane comprises substantially no Si—H bonds. As used in this manner, the term “substantially no Si—H bonds” means that the growth inhibitor comprises less than about 1% Si—H bonds based on the total number of silicon bonds. The growth inhibitor of some embodiments, forms surface termination —OSiRₓ on the source/drain material 120,121, replacing the —OH terminations. In some embodiments, the growth inhibitor comprises one or more of 1-(trimethylsilyl)pyrrolidine or bis(dimethylamino)dimethylsilane.

In some embodiments, the alkyl silane comprises at least one substituted or unsubstituted cyclic amine with a ring having in the range of 4 to 10 atoms. In some embodiments, the alkyl silane comprises a cyclic amine that has one nitrogen atom. In some embodiments, the cyclic amine has no more than one nitrogen atom and no less than one nitrogen atom. In one or more embodiments, the cyclic amine comprises pyrrolidine in which the nitrogen atom of the pyrrolidine is bonded to the silicon atom of the alkyl silane. In some embodiments, the alkyl silane comprises 1-(trimethylsilyl)pyrrolidine. In one or more embodiments, the alkyl silane consists essentially of 1-(trimethylsilyl)pyrrolidine. As used in this manner, the term “consists essentially of” means that the alkyl silane is greater than or equal to about 98% 1-(trimethylsilyl)pyrrolidine on a molecular basis.

The substrate can be exposed to the growth inhibitor at any suitable temperature and pressure. In some embodiments, the substrate is exposed to the growth inhibitor at a temperature in the range of about 50° C. to about 500° C., or in the range of about 100° C. to about 400° C. In some embodiments, the substrate is exposed to the growth inhibitor at a pressure in the range of about 30 Torr to about 120 Torr, or in the range of about 40 Torr to about 100 Torr, or in the range of about 50 Torr to about 90 Torr. In one or more embodiments, the substrate is exposed to the growth inhibitor in a thermal process without plasma.

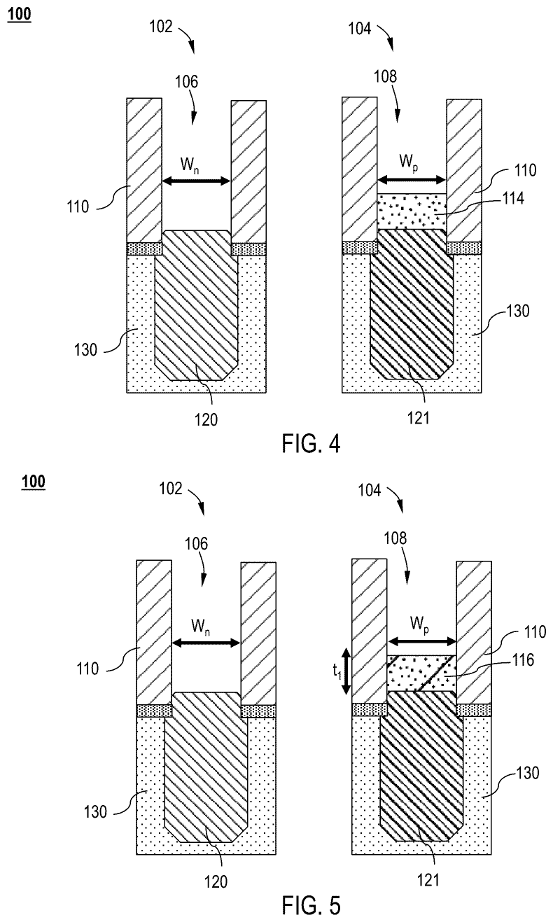

With reference to FIG. 1A and FIG. 4, at operation 18, a silicon-containing mask layer 114 may be selectively deposited on the source/drain material 121 of the p-transistor 104 and not (or substantially not) on the source/drain material 120 of the n-transistor 102. In other unillustrated embodiments, a silicon-containing mask layer 114 may be selectively deposited on the source/drain material 120 of the n-transistor 102 and not (or substantially not) on the source/drain material 121 of the p-transistor. The silicon-containing mask layer 114 may be deposited by any suitable means known to the skilled artisan. In one or more embodiments, the silicon-containing mask layer 114 can be deposited by any suitable means known to the skilled artisan. In one or more embodiments, the silicon-containing mask layer 114 is deposition, e.g., atomic layer deposition (ALD) or chemical vapor deposition (CVD), at a temperature less than 500° C., including less than 490° C., less than 450° C., less than 400° C., less than 350° C., and less than 300° C.

In one or more embodiments, the silicon-containing mask layer 114 has a low density. In some embodiments, the silicon-containing mask layer 114 has a density in a range of from 2.2 g/cm³ to 2.3 g/cm³.

The silicon-containing mask layer 114 may comprise any suitable material dielectric material known to the skilled artisan. As used herein, the term “dielectric material” refers to a layer of material that is an electrical insulator that can be polarized in an electric field. In one or more embodiments, the silicon-containing mask layer 114 comprises one or more of silicon nitride (SIN), silicon carbonitride (SiCN), silicon oxynitride (SiON), silicon oxycarbonitride (SiOCN), silicon boride (SiB), and silicon boron nitride (SiBN). In specific embodiments, the silicon-containing mask layer 114 comprises silicon nitride (SIN).

In one or more embodiments, deposition of the silicon-containing mask layer 114 is selective to the source/drain material 121 of the p-transistor 104 over the source/drain material 120 of the n-transistor 102, such that the silicon-containing mask layer 114 deposits on the source/drain material 121 of the p-transistor and not (or substantially not) on the source/drain material 120 of the n-transistor. As used in this regard, the term “selectively over” means that the film is formed on the source/drain material 121 of the p-transistor to a greater extent than the film can be formed on the source/drain material 120 of the n-transistor. For example, the silicon-containing mask layer 114 can be formed on the source/drain material 121 of the p-transistor than or equal to 20 times, 30 times, 40 times or 50 times thicker than the film is formed on the source/drain material 120 of the n-transistor. It one or more embodiments, the selectivity is greater than 2:1, greater than 5:1, greater than 10:1, or greater than 100:1.

In one or more embodiments, the silicon-containing mask layer 114 has a thickness in a range of from greater than 0 Å to 25 Å.

Without intending to be bound by theory, it is thought that the relatively low deposition temperature (i.e., less than 500° C.) leads to a poor-quality silicon-containing mask layer 114. Accordingly, the poor-quality silicon-containing mask layer 114 has a poor wet etch rate (WER) of greater than 300 Å.

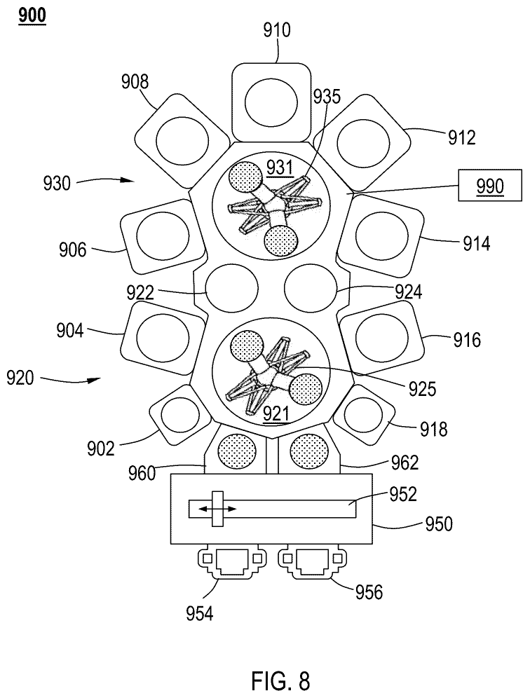

Formation of the silicon-containing mask layer 114 can occur by any suitable technique including, but not limited to, atomic layer deposition. In one or more embodiments, the silicon-containing mask layer 114 is formed in a single processing chamber. In other embodiments, the silicon-containing mask layer 114 is formed in a batch processing chamber, like that shown in FIG. 8. For example, the silicon-containing mask layer 114 may be formed by sequential exposure to a silicon precursor and a reactant. The silicon-containing mask layer 114 of some embodiments comprises one or more of SiN, SiO, SiON, SIC, SiCO, SiCN, or SiCON. In some embodiments, the silicon-containing mask layer 114 comprises silicon and one or more of oxygen, carbon, or nitrogen atoms. In some embodiments, the silicon-containing mask layer 114 is doped with one or more of boron (B), arsenic (As), or phosphorus (P) in an amount up to about two percent on an atomic basis.

In some embodiments, the silicon precursor comprises a silicon halide and the reactant comprises ammonia. In some embodiments, the silicon precursor comprises an organic silicon compound with or without halogen atoms. In some embodiments, the reactant comprises a nitrogen contributing species, an oxygen contributing species and/or a carbon contributing species. In some embodiments, the silicon precursor contributes one or more of nitrogen, oxygen, or carbon to the silicon-containing mask layer 114.

In one or more embodiments, the silicon-containing mask layer 114 is deposited using ALD or CVD, where the source/drain material 120 is exposed to a silicon precursor and ammonia to form the silicon-containing mask layer 114 on the source/drain material 120. The silicon precursor may include any suitable silicon precursor known to the skilled artisan. In one or more embodiments, the silicon precursor comprises a silane (SiH₄) or a poly-silane (SiₓH_{y}). In some embodiments, the poly-silane is selected from disilane (Si₂H₆), trisilane (Si₃H₈), tetrasilane (Si₄H₁₀), isotetrasilane, neopentasilane (Si₅H₁₂), cyclopentasilane (Si₅H₁₀), hexasilane (C₆H₁₄), cyclohexasilane (Si₆H₁₂).

In a single processing chamber, the substrate can be exposed to the silicon precursor and reactant in the same process region of the processing chamber. In a batch processing chamber, the substrate can be exposed to the silicon precursor and reactant in alternating process regions of the processing chamber.

The substrate can be exposed to the growth inhibitor in any suitable process chamber. In some embodiments, the substrate is exposed to the growth inhibitor in the pre-clean chamber. In some embodiments, the substrate is exposed to the growth inhibitor in a separate inhibiting chamber. In some embodiments, the substrate is exposed to the growth inhibitor in the batch processing chamber. For example, the process regions of the batch processing chamber can be changed so that the reactive gas flowing in the process regions is replaced with the growth inhibitor. After exposure to the growth inhibitor to form a blocking layer 132, the flow of the growth inhibitor in the process regions can be replaced with the silicon precursor and the reactant.

The film thickness can be deposited to a predetermined amount. After some time, the silicon-containing mask layer 114 may begin to deposit on the source/drain material 120 of the n-transistor even though the blocking layer 132 (from the growth inhibitor) is present. Without intending to be bound by any particular theory of operation, it is believed that the blocking layer 132 may be removed by the repeated exposures to the deposition reactants. To increase the thickness of the silicon-containing mask layer 114 and maintain the selectivity, the blocking layer 132 may be replenished periodically. In some embodiments, the substrate is exposed to the growth inhibitor after no more than 20, 30, 40, 50, 60, 70, 80, 90 or 100 atomic layer deposition cycles to deposit the silicon-containing mask layer 114. In some embodiments, the substrate is exposed to the growth inhibitor after formation of the silicon-containing mask layer 114 to a thickness in the range of about 30 Å to about 100 Å, or after formation of the silicon-containing mask layer 114 to a thickness up to about 20 Å, 30 Å, 40 Å, 50 Å, 60 Å or 70 Å.

Regeneration of the blocking layer 132 can be done by any suitable process. For example, the surface of the substrate can be purged with an inert gas (e.g., N₂ or He) for a time in the range of about 10 minutes to about 60 minutes at a pressure in the range of about 1 Torr to about 30 Torr. After purging the surface, the substrate can be exposed to the growth inhibitor again to regenerate the blocking layer 132. In some embodiments, the surface is purged for a time in the range of about 15 minutes to about 50 minutes, or a time in the range of about 20 minutes to about 40 minutes. In some embodiments, the surface is purged at a pressure in the range of about 10 Torr to about 25 Torr, or in the range of about 15 Torr to about 20 Torr.

In some embodiments, the blocking layer 132 is regenerated by first etching the whole surface of the substrate followed by exposure to the growth inhibitor. The etching process can be the same process used to pre-clean the surface or can be a different etching process.

The silicon-containing mask layer 114 can be formed at any suitable temperature. In some embodiments, the silicon-containing mask layer 114 is formed at a temperature in the range of about 200° C. to about 700° C., or in the range of about 300° C. to about 500° C., or in the range of about 350° C. to about 450° C. In some embodiments, the silicon-containing mask layer 114 is formed by a thermal process without plasma exposure. In one or more embodiments, thermal methods are used to selectively deposit the silicon-containing mask layer 114. In specific embodiments, the thermal process is performed without a plasma and without forming a seed layer. In other words, the silicon-containing mask layer 114 is selectively deposited directly on the source/drain material 120,121 without the deposition of an intervening layer of material. As used herein, “seed layer” refers to layer that is deposited directly on the source/drain material 120,121 to promote the subsequent formation/growth of a bulk layer thereon. In some cases, a bulk layer cannot be deposited directly on the source/drain material 120,121 without the deposition of an intervening layer of material, in which case a seed layer is required to enable bulk deposition. Advantageously, in one or more embodiments, the silicon-containing mask layer 114 is deposited directly on the source/drain material 120,121 as a bulk layer without the deposition of an intervening layer of material. In other embodiments, the silicon-containing mask layer 114 is formed by a plasma enhanced process.

The silicon-containing mask layer 114 deposited may have film properties that can be optimized or improved by post-deposition processing. For example, a silicon nitride film deposited may have a high wet etch rate. Exposing the film to a post-deposition process can be used to improve the wet etch rate of the deposited the silicon-containing mask layer 114. In some embodiments, the post-deposition process improves a quality of the film. In some embodiments, the quality of the film improved comprises one or more of the wet etch rate, refractive index, density, or hydrogen concentration.

The post-deposition process of some embodiments comprises exposing the substrate surface to a decoupled plasma. The decoupled plasma of one or more embodiments comprises helium. In some embodiments, the decoupled plasma consists essentially of helium. As used in this regard, the term “consists essentially of helium” means that the plasma comprises greater than or equal to about 95 atomic percent helium. The treatment pressure of some embodiments is in the range of about 1 mTorr to about 1 Torr. Lower pressures may be used for isotropic treatment of high aspect ratio structures. Wafer temperature during treatment can range from about room temperature to about 500° C.

In some embodiments, the processing platform has an environment that does not readily oxidize the substrate surface after cleaning. As used in this regard, the term “environment” refers to the ambient conditions within at least the central transfer station. The environment of the processing platform of some embodiments also includes any processing chamber used in the deposition process. For example, if two processing chambers are used in the process, the “environment” might include the two processing chambers and the central transfer station. In some embodiments, the environment of the processing platform comprises water vapor. The water vapor can be mixed with an inert gas or neat. In some embodiments, the water vapor is present in an inert gas in an amount in the range of about 0.1% to about 90% by weight. In some embodiments, the water vapor is present in an amount in the range of about 1% to about 80%, or in the range of about 2% to about 70%, or in the range of about 3% to about 60%, or in the range of about 4% to about 50%, or in the range of about 5% to about 40%, or in the range of about 10% to about 20% by weight. In some embodiments, the environment comprises one or more of nitrogen, hydrogen, helium, argon, krypton, neon, or xenon with water vapor in an amount greater than or equal to about 0.1%, 0.5%, 1%, 2%, 3%, 4%, 5%, 6%, 7%, 8%, 9%, 10%, 12%, 14%, 16%, 18%, or 20%.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

FIG. 5 shows operation 20 of FIG. 1A in which the silicon-containing mask layer 114 is densified to form a high-quality densified silicon-containing mask layer 116. The silicon-containing mask layer 114 may be densified by any suitable means known to the skilled artisan. In one or more embodiments, the silicon-containing mask layer 114 is densified by one or more of a thermal process or other treatment without adding oxygen into the silicon-containing layer. In one or more embodiments, the silicon-containing mask layer 114 is exposed to rapid thermal processing (RTP) to provide the high-quality densified silicon-containing mask layer 116. In other embodiments, densifying the silicon-containing dielectric layer comprises exposing the silicon-containing mask layer 114 to a high-density plasma at a temperature less than or equal to 500° C. and at a pressure less than 1 Torr. The high-density plasma may be selected from one or more of helium (He), hydrogen (H₂), neon (Ne), argon (Ar), krypton (Kr), and xenon (Xe).

In one or more embodiments, at operation 20, the selectively deposited silicon-containing mask layer 114 is densified at a temperature greater than 800° C. to provide a densified silicon-containing mask layer 116. In some embodiments, the silicon-containing mask layer 114 is treated at a temperature greater than 1000° C. to provide the densified silicon-containing mask layer 116. In one or more embodiments, after treatment, the densified silicon-containing mask layer 116 is a highly-quality film and has a wet etch rate of less than 4 Å/min, including a wet etch rate of less than 3 Å/min, less than 2 Å/min, and less than 1 Å/min.

In one or more embodiments, the densified silicon-containing mask layer 116 has a density gradient in a range if from 2.2 g/cm³ to 3.2 g/cm³. As used herein, the term “gradient” refers to variation in density throughout a thickness of a material. In other words, the densified silicon-containing mask layer 116 has a density gradient in which the density of the densified silicon-containing mask layer 116 gradually changes from least dense portion of the film adjacent the surface deposited upon (i.e., source/drain material 120,121).

In one or more embodiments, the densified silicon-containing mask layer 116 has a thickness in a range of from greater than 20 Å to less than 100 Å at the area of least density closest to the source/drain material 120,121. In one or more embodiments, the densified silicon-containing mask layer 116 has a thickness in a range of from 5 Å to 25 Å at the area of greatest density furthest from the source/drain material 120,121.

The method of one or more embodiments is an integrated method. In one or more embodiments, the method may be performed in one or more processing chamber without breaking vacuum.

With reference to FIG. 1A, at operation 22, in one or more embodiments, the surface of the high-quality densified silicon-containing mask layer 116 is optionally oxidized.

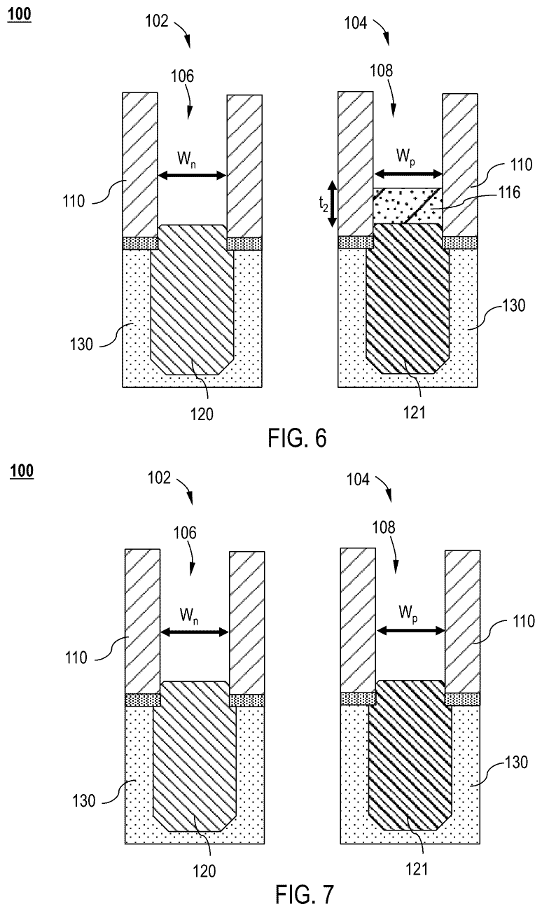

With reference to FIG. 1A and FIG. 6, formation of the n-channel and p-channel transistors may then proceed via traditional means. At operation 24, the n-channel or p-channel transistor source/drain is etched and cleaned. Without intending to be bound by theory, it is thought that the density gradient of the densified silicon-containing mask layer 116 advantageously impacts the subsequent processing of the transistor. For example, the presence of the densified silicon-containing mask layer 116 on the source/drain material 121 of the p-transistor 104 results in the lowest density material, closest to the source/drain material 121 not being removed during subsequent cleaning/etching. Thus, at operation 24, when the n-channel or p-channel transistor source/drain is etched and cleaned, only the densest portion of the densified silicon-containing mask layer 116 is removed, decreasing the thickness of the densified silicon-containing mask layer 116 from thickness t₁ to thickness t₂.

At operation 26, an epitaxial material is selectively formed on the NMOS and/or PMOS source/drain material. At operation 28, densified silicon-containing mask layer 116 is then removed from the NMOS and/or PMOS source/drain material. Without intending to be bound by theory, it is thought that the density gradient of the densified silicon-containing mask layer 116 advantageously impacts the subsequent processing of the transistor. For example, the lowest density material has a high etch rate, allowing subsequent mask removal (at operation 28 of FIG. 1A and FIG. 7) to occur without harsh conditions.

Referring to FIG. 1B and FIG. 2, in one or more alternative embodiments, at operation 54, the exposed surface(s), e.g., sidewall surface of the spacer 110 and the top surface of the source/drain material 120, 121, may be cleaned/pre-cleaned as described above with respect to method 10 of FIG. 1A.

With reference to FIG. 1B and FIG. 4, at operation 56, a silicon-containing mask layer 114 may be selectively deposited on the source/drain material 121 of the p-transistor 104 and not (or substantially not) on the source/drain material 120 of the n-transistor 102. In other unillustrated embodiments, a silicon-containing mask layer 114 may be selectively deposited on the source/drain material 120 of the n-transistor 102 and not (or substantially not) on the source/drain material 121 of the p-transistor. The silicon-containing mask layer 114 may be deposited by any suitable means known to the skilled artisan. In one or more embodiments, the silicon-containing mask layer 114 can be deposited by any suitable means known to the skilled artisan. In one or more embodiments, the silicon-containing mask layer 114 is deposition, e.g., atomic layer deposition (ALD) or chemical vapor deposition (CVD), at a temperature less than 600° C., including less than 500° C., less than 450° C., less than 400° C., less than 350° C., and less than 300° C.

In one or more embodiments, the silicon-containing mask layer 114 has a low density. In some embodiments, the silicon-containing mask layer 114 has a density in a range of from 2.2 g/cm³ to 2.3 g/cm³.

The silicon-containing mask layer 114 may comprise any suitable material dielectric material known to the skilled artisan. As used herein, the term “dielectric material” refers to a layer of material that is an electrical insulator that can be polarized in an electric field. In one or more embodiments, the silicon-containing mask layer 114 comprises one or more of silicon nitride (SiN), silicon carbonitride (SiCN), silicon oxynitride (SiON), silicon oxycarbonitride (SiOCN), silicon boride (SiB), and silicon boron nitride (SiBN). In specific embodiments, the silicon-containing mask layer 114 comprises silicon nitride (SIN).

In one or more embodiments, deposition of the silicon-containing mask layer 114 is selective to the source/drain material 121 of the p-transistor 104 over the source/drain material 120 of the n-transistor 102, such that the silicon-containing mask layer 114 deposits on the source/drain material 121 of the p-transistor and not (or substantially not) on the source/drain material 120 of the n-transistor. As used in this regard, the term “selectively over” means that the film is formed on the source/drain material 121 of the p-transistor to a greater extent than the film can be formed on the source/drain material 120 of the n-transistor. For example, the silicon-containing mask layer 114 can be formed on the source/drain material 121 of the p-transistor than or equal to 20 times, 30 times, 40 times or 50 times thicker than the film is formed on the source/drain material 120 of the n-transistor. It one or more embodiments, the selectivity is greater than 2:1, greater than 5:1, greater than 10:1, or greater than 100:1.

In one or more embodiments, the silicon-containing mask layer 114 has a thickness in a range of from greater than 0 Å to 25 Å.

Without intending to be bound by theory, it is thought that the relatively low deposition temperature (i.e., less than 500° C.) leads to a poor-quality silicon-containing mask layer 114. Accordingly, the poor-quality silicon-containing mask layer 114 has a poor wet etch rate (WER) of greater than 300 Å.

Formation of the silicon-containing mask layer 114 can occur by any suitable technique including, but not limited to, any of the methods described above with respect to operation 18 of FIG. 1A.

FIG. 5 shows operation 58 of FIG. 1B in which the silicon-containing mask layer 114 is densified to form a high-quality densified silicon-containing mask layer 116. The silicon-containing mask layer 114 may be densified by any suitable means known to the skilled artisan and according to any of the methods described above with respect to operation 20 of method 10. In one or more embodiments, the silicon-containing mask layer 114 is densified by one or more of a thermal process or other treatment without adding oxygen into the silicon-containing layer. In one or more embodiments, the silicon-containing mask layer 114 is exposed to rapid thermal processing (RTP) to provide the high-quality densified silicon-containing mask layer 116. In other embodiments, densifying the silicon-containing dielectric layer comprises exposing the silicon-containing mask layer 114 to a high-density plasma at a temperature less than or equal to 500° C. and at a pressure less than 1 Torr. The high-density plasma may be selected from one or more of helium (He), hydrogen (H₂), neon (Ne), argon (Ar), krypton (Kr), and xenon (Xe).

In one or more embodiments, at operation 20, the selectively deposited silicon-containing mask layer 114 is densified at a temperature greater than 800° C. to provide a densified silicon-containing mask layer 116. In some embodiments, the silicon-containing mask layer 114 is treated at a temperature greater than 1000° C. to provide the densified silicon-containing mask layer 116. In one or more embodiments, after treatment, the densified silicon-containing mask layer 116 is a highly-quality film and has a wet etch rate of less than 4 Å/min, including a wet etch rate of less than 3 Å/min, less than 2 Å/min, and less than 1 Å/min.

In one or more embodiments, the densified silicon-containing mask layer 116 has a density gradient in a range if from 2.2 g/cm³ to 2.8 g/cm³. As used herein, the term “gradient” refers to variation in density throughout a thickness of a material. In other words, the densified silicon-containing mask layer 116 has a density gradient in which the density of the densified silicon-containing mask layer 116 gradually changes from least dense portion of the film adjacent the surface deposited upon (i.e., source/drain material 120,121).

In one or more embodiments, the densified silicon-containing mask layer 116 has a thickness in a range of from greater than 20 Å to less than 100 Å at the area of least density closest to the source/drain material 120,121. In one or more embodiments, the densified silicon-containing mask layer 116 has a thickness in a range of from 5 Å to 25 Å at the area of greatest density furthest from the source/drain material 120,121.

The method of one or more embodiments is an integrated method. In one or more embodiments, the method may be performed in one or more processing chamber without breaking vacuum.

With reference to FIG. 1B, at operation 60, in one or more embodiments, the surface of the high-quality densified silicon-containing mask layer 116 is optionally oxidized.

With reference to FIG. 1B and FIG. 6, formation of the n-channel and p-channel transistors may then proceed via traditional means. At operation 62, the n-channel or p-channel source/drain is etched and cleaned. Without intending to be bound by theory, it is thought that the density gradient of the densified silicon-containing mask layer 116 advantageously impacts the subsequent processing of the transistor. For example, the presence of the densified silicon-containing mask layer 116 on the source/drain material 121 of the p-transistor 104 results in the lowest density material, closest to the source/drain material 121 not being removed during subsequent cleaning/etching. Thus, at operation 62, when the n-channel or p-channel source/drain is etched and cleaned, only the densest portion of the densified silicon-containing mask layer 116 is removed, decreasing the thickness of the densified silicon-containing mask layer 116 from thickness t₁ to thickness t₂.

At operation 64, an epitaxial material is selectively formed on the NMOS and/or PMOS source/drain material. At operation 66, densified silicon-containing mask layer 116 is then removed from the NMOS and/or PMOS source/drain material. Without intending to be bound by theory, it is thought that the density gradient of the densified silicon-containing mask layer 116 advantageously impacts the subsequent processing of the transistor. For example, the lowest density material has a high etch rate, allowing subsequent mask removal (at operation 66 of FIG. 1B and FIG. 7) to occur without harsh conditions.

Additional embodiments of the disclosure are directed to processing tools 900 for the formation of the logic or memory devices and methods described, as shown in FIG. 8.

In one or more embodiments, the processing tool 900 is a cluster tool that includes at least one central transfer station, e.g., first transfer chamber 921, and second transfer chamber 931, with a plurality of sides. At least one robot 925, 935 is positioned within the at least one central transfer station, e.g., first transfer chamber 921, and second transfer chamber 931, and is configured to move a robot blade and a wafer to each of the plurality of sides.

In one or more embodiments, the processing tool 900 is a cluster tool that comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, an inhibitor soaking chamber, a selective deposition (ALD) chamber, and a densification chamber (RTP). The particular arrangement of process chambers and components can be varied depending on the cluster tool and should not be taken as limiting the scope of the disclosure.

In the embodiment shown in FIG. 8, a factory interface 950 is connected to a front of the processing tool 900. The factory interface 950 includes a loading chamber 954 and an unloading chamber 956 on a front of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the processing tool 900, e.g., a cluster tool. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

In one or more embodiments, the processing tool 900 is a cluster tool that has a first section 920 and a second section 930. The first section 920 is connected to the factory interface 950 through load lock chambers 960, 962. The first section 920 includes a first transfer chamber 921 with at least one robot 925 positioned therein. The at least one robot 925 is also referred to as a robotic wafer transport mechanism. The first transfer chamber 921 is centrally located with respect to the load lock chambers 960, 962, processing chambers 902, 904, 916, 918, and buffer chambers 922, 924. The at least one robot 925 of some embodiments is a multi-arm robot capable of independently moving more than one wafer at a time. In some embodiments, the first transfer chamber 921 comprises more than one robotic wafer transfer mechanism. The at least one robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specifically integrated circuit or other type of hardware implementation, or as a combination of software and hardware. The software routine, when executed by the processor, transforms the general-purpose computer into a specific-purpose computer (controller) that controls the chamber operation such that the processes are performed.

In some embodiments, the system controller 990 has a configuration to control the selective deposition chamber to selectively deposit a silicon-containing mask layer in a region of a source/drain material, at a temperature less than 500° C. In some embodiments, the system controller 990 has a configuration to activate the plasma treatment chamber expose the silicon-containing mask layer to thermally treat the silicon-containing mask layer at a temperature greater than 800° C. to provide a densified silicon-containing mask layer having a wet etch rate of less than 4 Å/min.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising one or more of a pre-cleaning chamber, an inhibitor soaking chamber, a selective deposition chamber, a densification chamber, an oxidation chamber, and a controller connected to the central transfer station and the plurality of process stations, the controller configured to activate the robot to move the wafer between process stations, and to control a process occurring in each of the process stations. In one or more embodiments, the controller causes the processing tool to perform the operations of: pre-clean a top surface of a transistor, the transistor comprising a source/drain material; expose the top surface of the source/drain material to a growth inhibitor; selectively deposit a silicon-containing mask layer in a region of the source/drain material; and densify the silicon-containing mask layer. In one or more embodiments, the processing tool is maintained under vacuum during each processing operation.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A processing method to form a semiconductor device, the processing method comprising:
pre-cleaning one or more a first transistor or a second transistor;
selectively depositing a silicon-containing mask layer on one or more of a first region of the first transistor or a second region of the second transistor; and
densifying the silicon-containing mask layer to form a densified silicon-containing mask layer having a density gradient.

2. The processing method of claim 1, further comprising exposing one or more of the first transistor and the second transistor to a growth inhibitor prior to selectively depositing the silicon-containing mask layer.

3. The processing method of claim 1, wherein the first region and the second region independently comprise one or more of silicon (Si) and silicon germanium (SiGe).

4. The processing method of claim 3, wherein the first region and the second region are independently doped with one or more of phosphorous (P) or boron (B).

5. The processing method of claim 1, wherein the silicon-containing mask layer comprises one or more of silicon nitride (SiN), silicon carbonitride (SiCN), silicon oxynitride, silicon oxycarbonitride (SiOCN), silicon boride (SiB), and silicon boron nitride (SiBN).

6. The processing method of claim 1, wherein selectively depositing the silicon-containing mask layer comprises deposition at a temperature of less than 500° C.

7. The processing method of claim 1, wherein densifying the silicon-containing mask layer comprises exposing the silicon-containing mask layer to a rapid thermal processing (RTP) process.

8. The processing method of claim 1, wherein densifying the silicon-containing mask layer comprises exposing the silicon-containing mask layer to a high-density plasma at a temperature less than or equal to 500° C. and at a pressure less than 1 Torr, the high-density plasma selected from one or more of helium (He), hydrogen (H₂), neon (Ne), argon (Ar), krypton (Kr), and xenon (Xe).

9. The processing method of claim 1, further comprising oxidizing the densified silicon-containing mask layer.

10. The method of claim 1, further comprising:
removing the densified silicon-containing mask layer from one of the first transistor or the second transistor to expose the first region or the second region;
selectively growing an epitaxial layer on the exposed first region or the exposed second region; and
removing the densified silicon-containing mask layer from the other of the first transistor or the second transistor to expose the other of the first region or the second region.

11. The processing method of claim 1, further comprising:
exposing the densified silicon-containing mask layer to a growth inhibitor;
selectively depositing a second silicon-containing mask layer on the first region or on the second region; and
densifying the second silicon-containing mask layer.

12. The processing method of claim 1, further comprising:
selectively depositing a second silicon-containing mask layer on one or more of the first region or the second region; and
densifying the second silicon-containing mask layer.

13. The processing method of claim 1, wherein the processing method is performed in a processing tool without breaking vacuum.

14. The processing method of claim 2, further comprising:
pre-cleaning a top surface of the densified silicon-containing mask layer;
selectively depositing a second silicon-containing mask layer on one or more of the first region or the second region; and
densifying the second silicon-containing mask layer.

15. The processing method of claim 2, further comprising:
selectively depositing a second silicon-containing mask layer on one or more of the first region or the second region; and
densifying the second silicon-containing mask layer.

16. A processing method to form a logic or memory device, the processing method comprising:
pre-cleaning one or more of a first transistor or a second transistor;
exposing one or more of the first transistor or the second transistor to a growth inhibitor;
selectively depositing a silicon-containing mask layer on a first region of the first transistor or on a second region of the second transistor;
densifying the silicon-containing mask layer to form a densified silicon-containing mask layer having a density gradient; and
repeating one or more of: pre-cleaning one or more of the first transistor or the second transistor, exposing one or more of the first transistor or the second transistor to the growth inhibitor, selectively depositing the silicon-containing mask layer, and densifying the silicon-containing mask layer,
wherein the processing method is performed in a processing tool without breaking vacuum.

17. A processing tool comprising:
a central transfer station comprising a robot configured to move a wafer;
a plurality of process stations; and
a controller configured to activate the robot to move the wafer between the process stations, and to control a process comprising:
pre-cleaning one or more of a first transistor or a second transistor;
selectively depositing a silicon-containing mask layer on one or more of a first region of the first transistor or a second region of the second transistor; and
densifying the silicon-containing mask layer to form a densified silicon-containing mask layer having a density gradient,
wherein the operations are performed without breaking vacuum.

18. The processing tool of claim 17, wherein the processing tool is selected from the group consisting of a single processing chamber and a batch processing chamber.

19. The processing tool of claim 17, wherein the process further comprises: exposing one or more of the first transistor or the second transistor to a growth inhibitor prior to selectively depositing the silicon-containing mask layer.

20. The processing tool of claim 17, wherein the process further comprises: oxidizing the densified silicon-containing mask layer.
